(19) United States
(12) Patent Application Publication
(10) Pub. No.: US 2023/0299230 A1
(43) Pub. Date: Sep. 21, 2023

(54) LIGHT EMITTING DEVICE

(71) Applicant: The Regents of the University of Michigan, Ann Arbor, MI (US)

(72) Inventors: Yuanpeng WU, Ann Arbor, MI (US); Yixin XIAO, Ann Arbor, MI (US); Ishtiaque NAVID, Ann Arbor, MI (US); Yakashita MALHOTRA, Ann Arbor, MI (US); Zetian MI, Ann Arbor, MI (US)

(21) Appl. No.: 18/200,375

(22) Filed: May 22, 2023

Related U.S. Application Data
(63) Continuation of application No. 16/044,337, filed on Jul. 24, 2018.
Application No. 16/044,337 is a continuation of application No. 17/956,571, filed on Sep. 29, 2022.
Application No. 17/956,571 is a continuation of application No. 14/776,120, filed on Sep. 14, 2015, now Pat. No. 11,502,219.
Application No. 14/776,120 is a continuation of application No. 17/800,878, filed on Aug. 18, 2022.
Application No. 17/800,878 is a continuation of application No. 17/745,753, filed on May 16, 2022.
Application No. 17/745,753 is a continuation of application No. PCT/US22/29397, filed on May 16, 2022.
(60) Provisional application No. 63/344,491, filed on May 20, 2022.
(60) Provisional application No. 62/536,449, filed on Jul. 24, 2017.
(60) Provisional application No. 61/781,806, filed on Mar. 14, 2013.
(60) Provisional application No. 61/904,493, filed on Nov. 15, 2013.
(60) Provisional application No. 62/978,168, filed on Feb. 18, 2020.
(60) Provisional application No. 63/188,971, filed on May 14, 2021.
(60) Provisional application No. 63/188,971, filed on May 14, 2021.

(51) Int. Cl. H01L 33/06; H01L 33/32; H01L 33/00; G02B 6/122; H01L 33/18

(52) U.S. Cl. CPC H01L 33/06; H01L 33/32; H01L 33/007; G02B 6/1225; H01L 33/18; H01S 5/34333

(57) ABSTRACT

Systems and methods presented herein include efficient and effective Light Emitting Devices (LED) devices. In one embodiment, a light emitting device comprises: a substrate comprising silicon; a first portion comprising a group III-V compound component with a first type of doping; a second portion comprising an active region, a shell comprising a gradient configuration with piezoelectric field compensation characteristics; and a third portion comprising a group III-V compound component with a second type of doping, The silicon substrate is coupled to the first portion. The first portion and shell are coupled to the second portion with is in turn coupled to the third portion. The active region comprises a quantum core structure with strain compensation barriers and polarization doping. The strain compensated barriers form multiple quantum wells. In one embodiment, the strain compensation barriers include AlGaN in a configuration that compensates tensile strain within the active region. The AlGaN can also be configured to induce polarization charges and enhance indium incorporation. In one embodiment, the shell comprises AlGaN with a negative Al composition gradient.

### RELATED APPLICATIONS

The present invention claims the benefit of and priority to USPTO Provisional application Number:
63/344,491 entitled “LIGHT EMITTING DIODE” (Attorney Docket Number TRTM-0020-00.00) filed on May 20, 2022,
   and is a continuation of and claims priority to USPTO application Number:
Ser. No. 16/044,337 entitled Core-Shell InGaN/AlGaN Quantum Nanowire Photonic Structures (Attorney Docket Number TRTM-P0005) filed on Jul. 24, 2018, which claims priority to and benefit of USPTO Provisional Application No. 62/536,449 Core-Shell InGaN/AlGaN Quantum Nanowire Photonic Structures (Attorney Docket Number 30275/52065) filed on Jul. 24, 2017;
   and is also a continuation of and claims priority to USPTO application Number:
Ser. No. 17/956,571 entitled Methods and Devices for Solid State Nanowire Devices (Attorney Docket Number TRTM-P0007-04C03US) filed on Sep. 29, 2022, which is a continuation of USPTO application Ser. No. 14/776,120 filed on Sep. 14, 2015, which is a 371 of international application PCT/CA2014/000234 filed Mar. 14, 2014 which claims the benefit of provisional applications 61/781,806 filed Mar. 14, 2013 and 61/904,493 filed on Nov. 15, 2013;
   and is also a continuation of and claims priority to USPTO application Number:
Ser. No. 17/800,878 entitled Micrometer Scale Light-emitting Diodes (Attorney Docket Number TRTM-P0010-02N02US) filed on Aug. 18, 2022, which is a 371 of international application PCT/US2021/018559 filed Feb. 18, 2021, which claims the benefit of provisional applications 62/978,168 filed Feb. 18, 2020;
   and is also a continuation of and claims priority to USPTO application Number:
Ser. No. 17/745,753 entitled High Efficiency InGaN Light Emitting Diodes (Attorney Docket Number TRTM-P0014) filed on May 16, 2022, and of international application PCT/US2022/29397 filed May 16, 2022, both of which claim priority to and benefit of USPTO Provisional Application No. 63/188,971 entitle High Efficiency INGaN Nanocrystal tunnel Junction Micro LEDs (Attorney Docket Number TRTM-0014.00.00) filed on May 14, 2021;
   all of which are incorporated herein by reference.

### BACKGROUND

Micro-LEDs (μLEDs) that can be monolithically integrated with CMOS electronics and have dimensions as small as one micrometer are in demand for various applications (e.g., the emerging revolution in virtual reality (VR)/augmented reality (AR), etc.). Achieving such μLEDs, however, has remained a daunting challenge. The past two decades have witnessed the solid-state lighting revolution powered by GaN-based broad area light emitting diodes (LEDs), which generally have lateral dimensions on the order of millimeter. For the emerging revolution in virtual reality (VR)/augmented reality (AR), however, LEDs with dimensions as small as one micrometer (e.g., LEDs with surface area approximately one million times smaller than conventional broad area devices, etc.) are in demand. It is desired that the micro, or submicron scale LEDs (μLEDs) can exhibit high efficiency, high brightness, highly stable operation, ultralow power consumption, and full-color emission, and can be monolithically grown on Si for integration with CMOS electronics. To date, however, it has remained a daunting challenge to achieve high efficiency μLEDs. For example, the external quantum efficiency often drops to well below 1% when the lateral dimensions of conventional high efficiency InGaN quantum well LEDs are shrunk to micrometer, or submicron scale. The efficiency cliff of μLEDs is primarily due to surface damage and the resulting nonradiative surface recombination induced by top-down etching of conventional quantum well structures. The efficiency cliff typically becomes even more severe for long wavelength (e.g., green LEDs, red LEDs, greater than 500 nm, 500-650 nm, etc.) due to the enhanced defect formation related to the large misfit between InN and GaN. Performance of such long wavelength devices also often suffer severely from quantum-confined Stark effect (QCSE).

### SUMMARY

Systems and methods presented herein include efficient and effective Light Emitting Devices (LED) devices. In one embodiment, a light emitting device comprises: a substrate comprising silicon; a first portion comprising a group III-V compound component with a first type of doping; a second portion comprising an active region, a shell comprising a gradient configuration with piezoelectric field compensation characteristics; and a third portion comprising a group Ill-V compound component with a second type of doping, The silicon substrate is coupled to the first portion. The first portion and shell are coupled to the second portion with is in turn coupled to the third portion. The active region comprises a quantum core structure with strain compensation barriers and polarization doping. The strain compensated barriers form multiple quantum wells. In one embodiment, the strain compensation barriers include AlGaN in a configuration that compensates tensile strain within the active region. The AlGaN can also be configured to induce polarization charges and enhance indium incorporation. In one embodiment, the shell comprises AlGaN with a negative Al composition gradient.

In one embodiment, the first portion, second portion, and third portion comprise nanostructure components (e.g., forming a nanowire, etc.). In one exemplary implementation, a nanowire is one of a plurality of nanowires included in the light emitting device. The first portion, second portion, third portion and shell form a nanowire core with polarization doping configured to enable stable operation and light emission. The light emission can be a long wavelength range. The light emitting device can be configured to operate with negligible quantum-confined Stark effect. In one exemplary implementation, the light emitting device is configured to create stable wavelength emissions.

In one embodiment, the substrate includes electronics (e.g., CMOS electronics, etc.). In one exemplary implementation, the light emitting device is a micro-light emitting device and the substrate includes electronics monolithically integrated in the micro-light emitting device (e.g., a micro-light emitting diode (PLED), etc.).

In one embodiment, a method comprises: forming a substrate comprising silicon; forming a first portion comprising a group III-V compound component with a first type of doping; forming a second portion comprising an active region, wherein the active region comprises a quantum core structure with strain compensated barriers, wherein the second portion is coupled to the first portion; forming a shell coupled to the second portion, wherein the shell comprises polarization doping, and forming a third portion comprising a group III-V compound component with a second type of doping, wherein the third portion is coupled to the second portion. Forming the substrate includes forming electronic components in the silicon. The substrate, the first portion, the second portion, shell and third portion are monolithically formed. In one exemplary implementation, the first portion, the second portion, shell, and third portion are grown on substrate in a configuration that reduces thermal accumulation within the device area.

### BRIEF DESCRIPTION OF THE DRAWINGS

The accompanying drawings, which are incorporated in and form a part of this specification, are included for exemplary illustration of the principles of the present invention and are not intended to limit the present invention to the particular implementations illustrated therein. The drawings are not to scale unless otherwise specifically indicated.

FIG. 1A is a block diagram of a light emitting device in accordance with one embodiment.

FIG. 1B is a block diagram of schematic of InGaN/AlGaN MQW nanowire heterostructures grown on Si substrate in accordance with one embodiment.

FIG. 1C is a block diagram of a bird's eye view of an exemplary SEM image of InGaN/AlGaN nanowire arrays.

FIG. 1D is a block diagram of an exemplary Cross-sectional STEM image of the nanowire on Si substrate showing the termination of threading dislocations (TDs) on the sidewall of n-GaN nanowire before reaching the active region in accordance with one embodiment.

FIG. 2A is a block diagram of an exemplary low-magnification HAADF STEM image of InGaN/AlGaN nanowire heterostructures grown on GaN/AlN/Si substrate in accordance with one embodiment.

FIG. 2B is a block diagram of an exemplary HAADF-STEM image in accordance with one embodiment.

FIG. 2C illustrates an exemplary In-map in accordance with one embodiment.

FIG. 2D illustrates an exemplary Al-map in accordance with one embodiment.

FIG. 2E illustrates an exemplary Ga-map in accordance with one embodiment.

FIG. 2F is an illustration of an exemplary high magnification image in accordance with one embodiment.

FIG. 2G is an exemplary EDS line scan along the arrow as shown in the inset in accordance with one embodiment.

FIG. 2H is an exemplary EDS line scan along the arrow as shown in the inset in accordance with one embodiment.

FIG. 3A is graph of exemplary room-temperature power-dependent PT spectra of Sample A at 300 K with excitation power varied ˜3 orders of magnitude in accordance with one embodiment.

FIG. 3B is a graph of exemplary emission peak energy vs. excitation power for Sample A (green circles) and Sample B (blue squares) in accordance with one embodiment.

FIG. 3C is a graph of exemplary calculated electron density distribution with the presence of polarization doping (blue curve)/background doping (gray curve) in accordance with one embodiment.

FIG. 3D is a graph of an exemplary PL comparison of Sample A and Sample C measured under the same excitation power in accordance with one embodiment.

FIG. 4A is a block diagraph of an exemplary HAADF image of the active region of a sample in accordance with one embodiment.

FIG. 4B is a block diagram of an exemplary LAADF image in accordance with one embodiment.

FIG. 4C is a block diagram of an exemplary LAADF image of the active region and underlying GaN of a sample in accordance with one embodiment.

FIG. 4D is a graph of an exemplary LAADF line profile along the green dashed line in (b) and blue dashed line in (c) in accordance with one embodiment.

FIG. 5A is a block diagram of an exemplary HAADF-STEM image of the cross section of the as fabricated InGaN/AlGaN μLED with areal size of ˜900×900 nm² in accordance with one embodiment.

FIG. 5B in a graph of an exemplary I-V characteristics of as-fabricated InGaN/AlGaN nanowire μLEDs measured at room temperature in accordance with one embodiment, wherein negligible leakage current is observed at reverse bias.

FIG. 5C is a graph of an exemplary EL spectra measured under injection currents from 350 A/cm² to 4,100 A/cm² for an InGaN/AlGaN μLED in accordance with one embodiment.

FIG. 5D is a graph of exemplary variation of peak position vs. injection current in accordance with one embodiment.

FIG. 6 is a flow chart of exemplary method in accordance with one embodiment.

### DETAILED DESCRIPTION

Reference will now be made in detail to the various embodiments of the present disclosure, examples of which are illustrated in the accompanying drawings. While described in conjunction with these embodiments, it will be understood that they are not intended to limit the disclosure to these embodiments. On the contrary, the disclosure is intended to cover alternatives, modifications and equivalents, which may be included within the spirit and scope of the disclosure. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure.

The figures are not necessarily drawn to scale, and only portions of the devices and structures depicted, as well as the various layers that form those structures, are shown. For simplicity of discussion and illustration, only one or two devices or structures may be described, although in actuality more than one or two devices or structures may be present or formed. Also, while certain elements, components, and layers are discussed, embodiments according to the invention are not limited to those elements, components, and layers. For example, there may be other elements, components, layers, and the like in addition to those discussed.

Systems and methods presented herein include efficient and effective light emitting devices (e.g., Light Emitting Diode (LED), etc.). In one embodiment, an=light emitting device includes an introduced core-shell structure and polarization doping. The introduced core-shell structure and polarization doping enable stable operation and light emission (e.g., with negligible quantum-confined Stark effect, etc.). In one embodiment, a light emitting device includes a barrier (e.g., an AlGaN barrier, etc.) that effectively compensates the tensile strain within the active region, which significantly reduces the strain distribution and results in higher indium incorporation (e.g., in comparison to a conventional GaN barrier, etc.). In one embodiment, a light emitting device configuration can be considered a Micro-LED (LED). In one embodiment, an light emitting device is grown on a substrate in a configuration that reduces thermal accumulation within the device area. It is appreciated that various methods and aspects of growing a light emitting device (e.g., μLED, etc.) can be implemented (e.g., grown on a silicon (Si) substrate, monolithically grown, grown directly on the substrate, grown with lateral dimensions as small as 0.9 μm, etc.). The presented novel embodiments provide new insights and a viable path for the design, fabrication, and integration of high-performance LEDs for various applications (e.g., on-chip optical communication, emerging virtual reality/augmented reality (VR/AR) devices and systems, etc.).

Recent advances of III-nitride nanostructures (e.g., nanowires, etc.) have provided a promising path to overcome the efficiency cliff of μLEDs. Typically, μLEDs made of bottom-up nanostructures are free from etch-induced damage on the surface and misfit dislocations in the device active region. However, traditionally there have been few studies of μLEDs monolithically grown on Si substrate, due to the large lattice mismatch between GaN and Si. A significant traditional challenge for nanowire μLEDs, particularly for those operating at long wavelengths, however, in the presence of point defects, in both the device active region and on the lateral surfaces, largely due to the relatively low growth temperature required to enhance indium incorporation. In one embodiment, such a challenge is addressed by a strain-compensated active region design, In one exemplary implementation, a strain-compensated active region design includes replacing a GaN barrier in the quantum well active region with an AlGaN barrier for a smaller mismatch strain energy, and therefore a higher growth temperature to reduce defect formation. Moreover, with a wider bandgap, AlGaN can provide stronger carrier confinement within the InGaN active region and reduces the carrier leakage related to non-radiative recombination. However, in one exemplary implementation higher Al composition may cause an enhanced piezoelectric field for quantum wells (QWs) grown on the c-plane, which reduces the oscillator strength of the QW fundamental transition and causes a carrier-density sensitive emission.

Approaches presented herein can address the traditional conundrums associated with achieving stable μLED operations. In one embodiment, an light emitting device includes a shell configured to mitigate/overcome piezoelectric field issues. In one exemplary implementation, an AlGaN/GaN shell around the active region with a negative Al composition gradient is included along the c-axis of InGaN nanowire μLEDs. In one embodiment, a μLED is fabricated based on a N-polar nanowire array synthesized through a bottom-up selective area epitaxy (SAE) process. In one exemplary implementation, the devices exhibits strong green emission with a lateral dimension below 1 pam. Detailed power-dependent photoluminescence (PL) measurements and current-dependent electroluminescence (EL) measurements show negligible shifts in the peak energy, contrasting the blue-shifts commonly measured from InGaN/GaN QWs because of quantum-confined Stark effect (QCSE). In one embodiment, the composition gradient GaN/AlGaN shell around the InGaN QWs can effectively induce bound positive charges and free electrons, which screen the internal electrostatic field within the InGaN QW. In one exemplary implementation, an AlGaN barrier can effectively compensate the tensile strain caused by InGaN QWs and lead to an enhanced indium incorporation as well as longer emission wavelengths. Moreover, light emitting devices are achieved on a silicon (Si) substrate instead of commonly used sapphire substrate, which reduces thermal accumulation within the device area and enables seamless integration with CMOS electronics. In one embodiment, the presented novel light emitting device systems and methods provide new insights and a viable approach for achieving high performance light emitting devices (e.g., μLEDs, etc.) with highly ultra stable operation on Si for their emerging applications in VR/AR and ultrahigh resolution mobile displays.

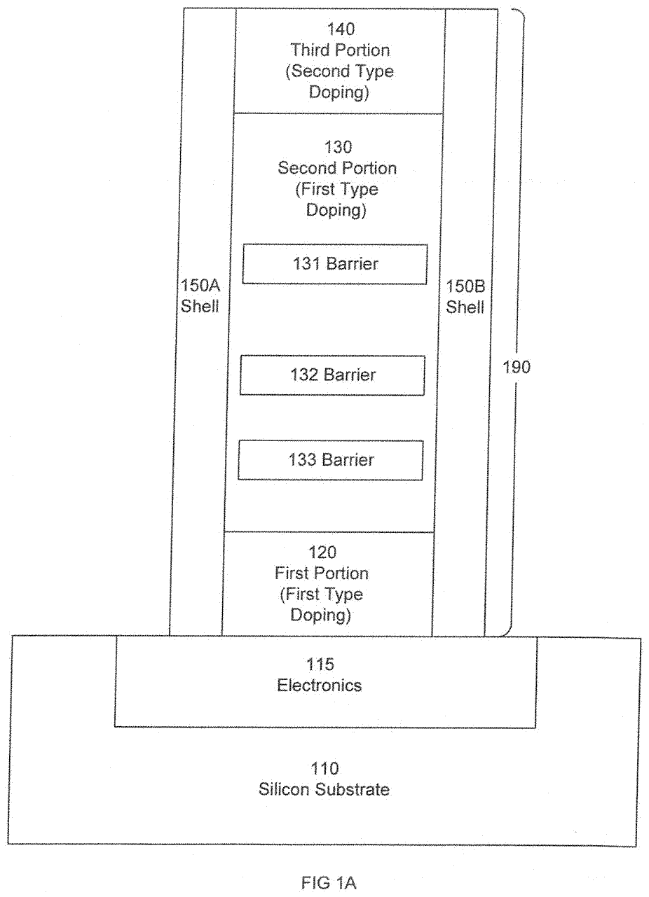

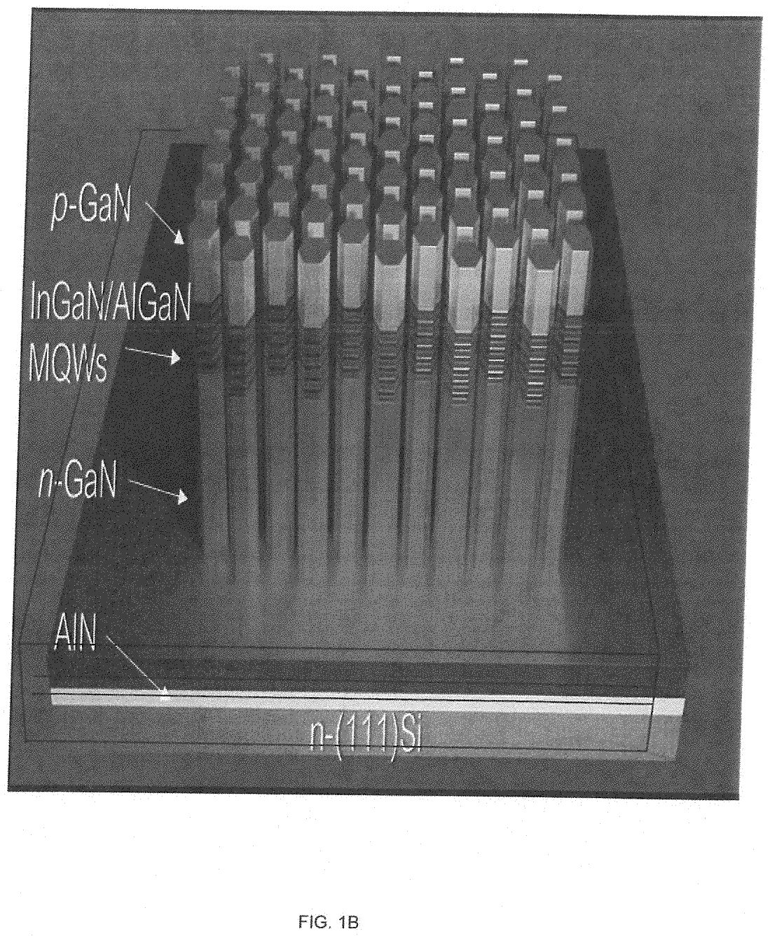

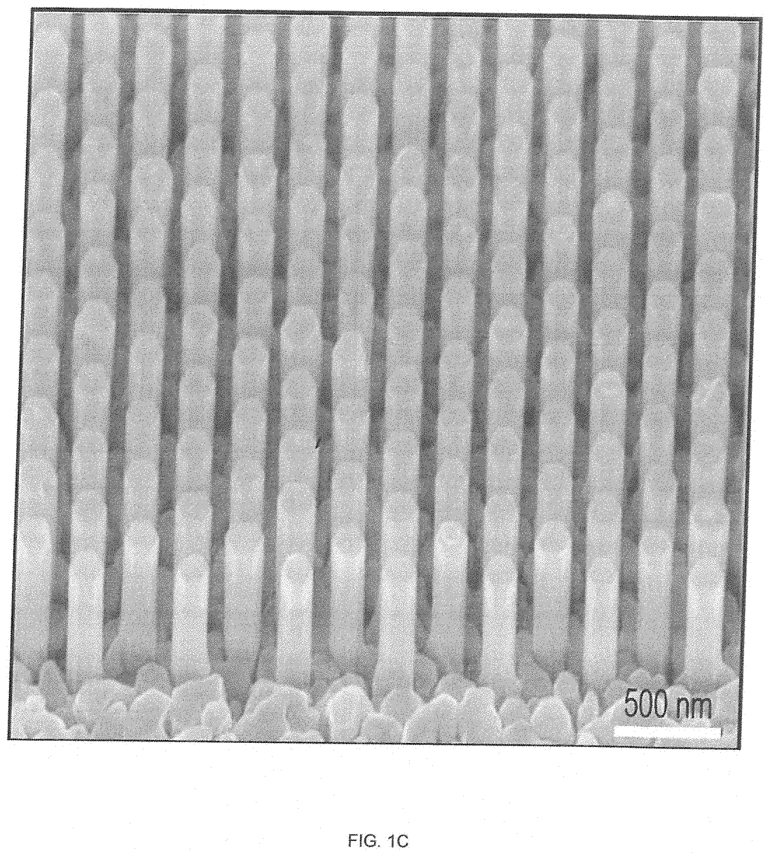

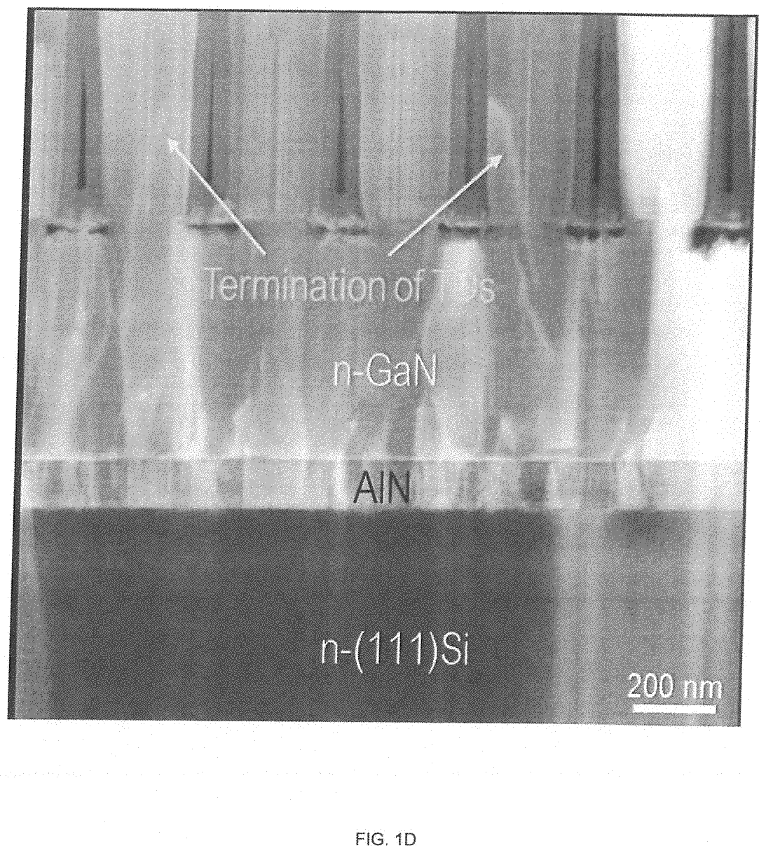

FIG. 1A is a block diagram of a light emitting device 100 in accordance with one embodiment. Light emitting device 100 includes silicon substrate 110 and component 190. In one exemplary implementation, core component 190 is a nanostructure, (e.g., nanowire, etc.). Silicon substrate 110 includes electronics Ill (e.g., CMOS, etc.). First portion 121 is coupled to second portion 122, which is coupled to third portion 140. Shell 150 (including portions 150A and 150B) is coupled to and surrounds first portion 121, second portion 122, and third portion 140.

First portion 121 includes a group III-V compound component with a first type of doping. Second portion 130 includes an active region, wherein the active region comprises a quantum core structure with strain compensation barriers (e.g., 131, 132, and 133, etc.) and polarization doping. The shell comprises a gradient configuration with piezoelectric field compensation characteristics. The third portion 140 includes a group III-V compound component with a second type of doping.

FIG. 1B is a block diagram schematic of InGaN/AlGaN MQW nanowire heterostructures grown on Si substrate in accordance with one embodiment. As schematically shown in Figure B, each nanowire includes ˜450 nm Si-doped GaN, six periods of InGaN/AlGaN QWs, and ˜170 nm Mg-doped GaN. Additional description is set forth in the Methods section below.

FIG. 1C is a block diagram of a bird's eye view of an exemplary SEM image of InGaN/AlGaN nanowire arrays in accordance with one embodiment. In one exemplary implementation, FIG. 1C is an exemplary representative SEM image of a nanowire array grown by SAE on Si substrate. Each nanowire is enclosed by 6 equivalent m-planes on the sidewalls and a flat top c-plane, contrasting the pyramidal (11̅0n) top surfaces observed in metal-polar nanowires. The N-polarity of the nanowires is further confirmed by KOH etching as shown in Figure S2, wherein the top surface is roughened with pyramidal islands. Despite a possible high defect density within the GaN epilayer, in one embodiment, the majority (>85%) of the nanowires feature nearly perfect crystallinity, indicating a filtering effect of nanowire structure on propagating dislocations.

FIG. 11) is a block diagram of an exemplary cross-sectional STEM image of a nanowire on Si substrate showing the termination of threading dislocations (TDs) on the sidewall of n-GaN nanowire before reaching the active region in accordance with one embodiment. In one exemplary implementation, the threading dislocation density (TDD) within the GaN film is measured ˜4×10¹⁰ cm⁻². The TDs are observed to terminate on the sidewall of the nanowires, significantly reducing the defect density in the active region as shown in FIG. 1C, in accordance with one embodiment. In one exemplary implementation, this is exceptionally true for nanowires with diameters less than 150 nm, whereas larger diameter (over 200 nm) nanowires have a higher dislocation density as shown in Figure S3.

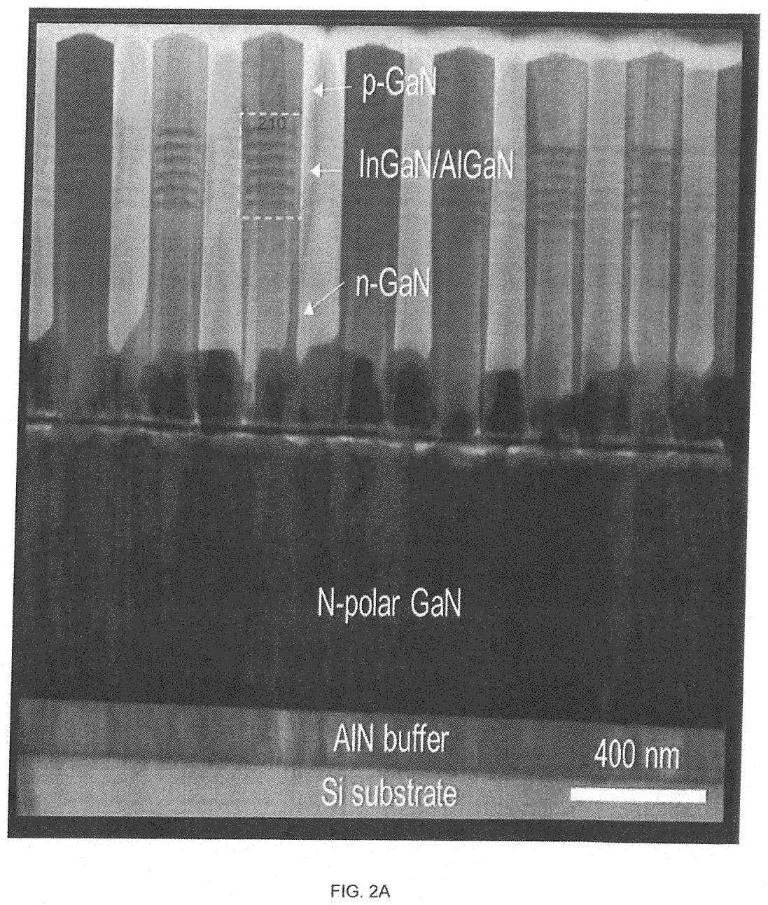

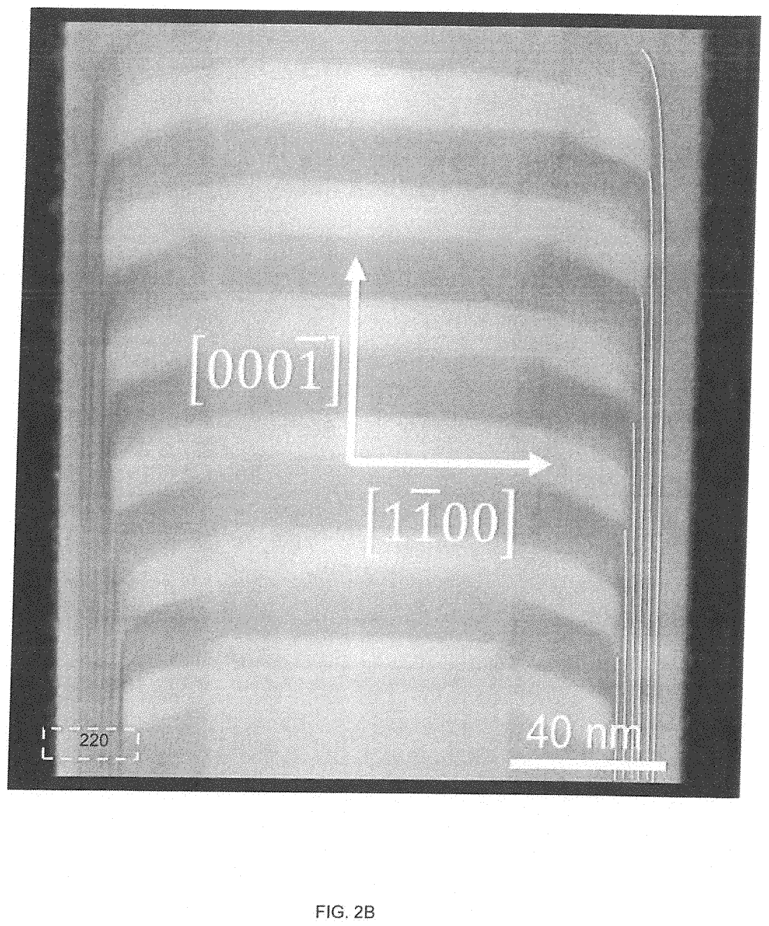

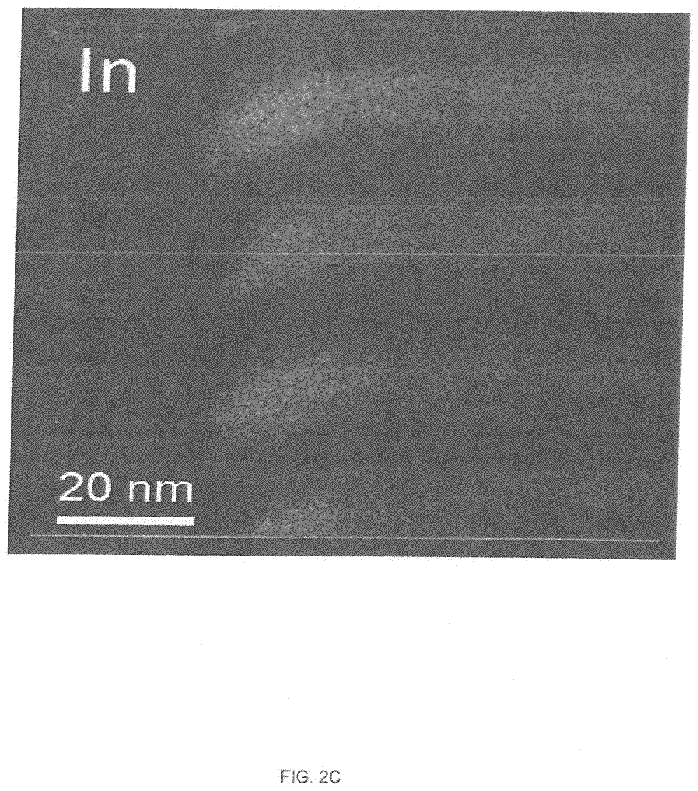

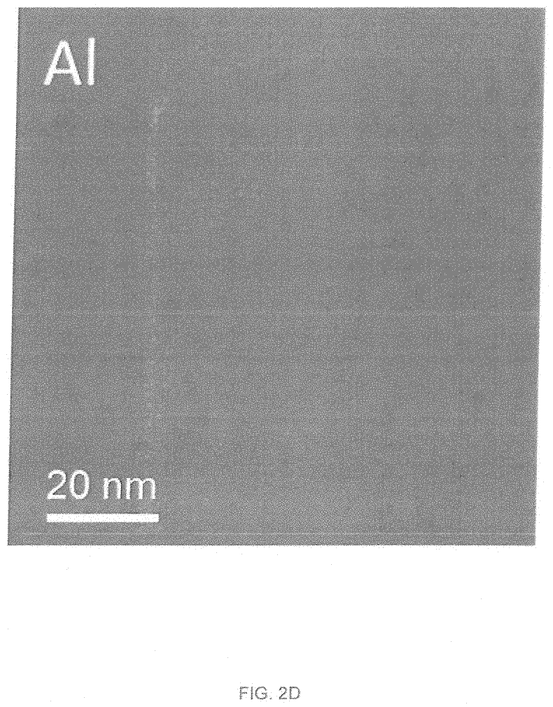

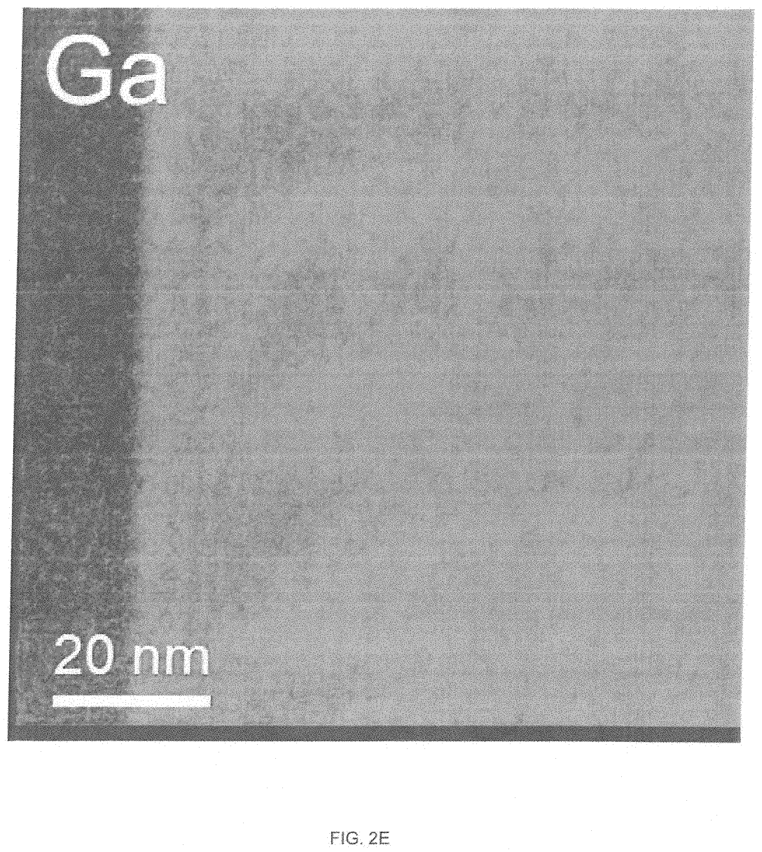

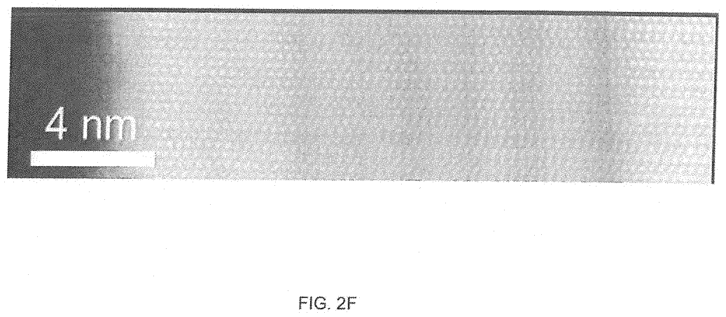

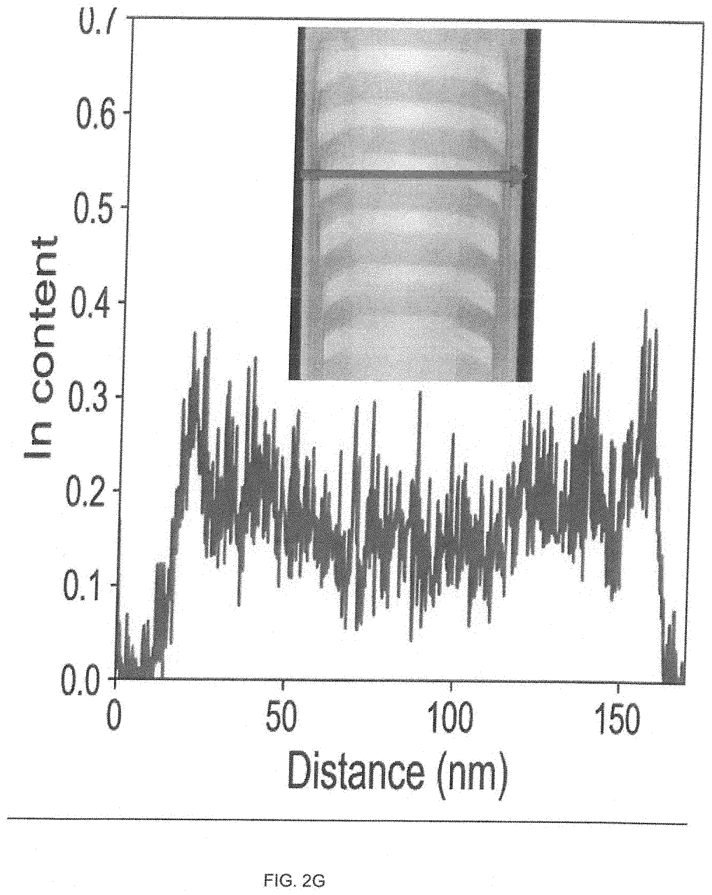

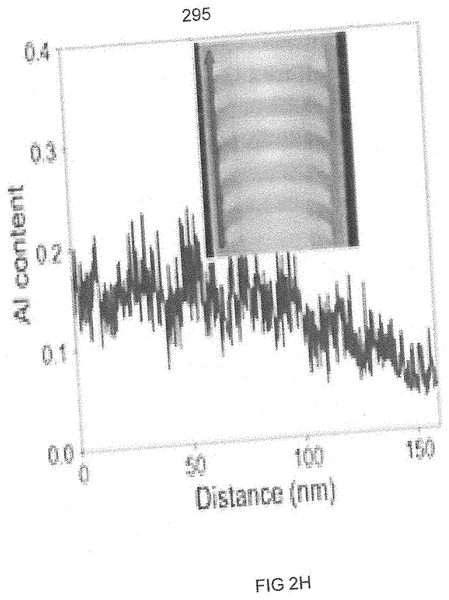

FIG. 2A is a block diagram of an exemplary HAADF-STEM image in accordance with one embodiment. In one exemplary implementation a region shown by dashed line box 210 in FIG. 2A includes an exemplary low-magnification HAADF STEM image of InGaN/AlGaN portion of an active region in a nanowire heterostructure grown on GaN/AlN/Si substrate. FIG. 2A shows exemplary low magnification bright-field scanning transmission electron microscopy (STEM) image of the InGaN/AlGaN p-i-n heterostructure on Si substrate, wherein individual layers of the heterostructure can be clearly distinguished, in accordance with one embodiment. The corresponding structural electron dispersive spectroscopy (EDS) mapping of the Si, Ga and Al elements clearly illustrates the AlInGaN SAE nanowires, GaN epi-film, AlN buffer and the Si substrate as shown in Figure S4, in accordance with one embodiment.

FIG. 2B is a block diagram of an exemplary HAADF-STEM image in accordance with one embodiment. In one exemplary implementation, the HAADF-STEM image corresponds to the image of the box 210 region in FIG. 2A. FIG. 2B shows the high angle angular dark field (HAADF) image of the active region, which includes 6 pairs of InGaN/AlGaN QWs. The InGaN QWs show approximately uniform thicknesses (˜12 nm) from QW to QW separated by AlGaN barriers along the c-axis, in accordance with one embodiment. The edge of QWs is found to be on the semipolar plane instead of c-plane, indicating a partially faceted top surface during nanowire growth. The repeating growth of the six InGaN/AlGaN quantum wells forms intensity modulated shells around the active region.

In one embodiment, EDS elemental analyses (e.g., FIGS. 2c-2e, etc.) illustrate exemplary distribution variations of different elements in the active region. FIG. 2C illustrates an exemplary In-map in accordance with one embodiment. FIG. 2D illustrates an exemplary Al-map in accordance with one embodiment. FIG. 2E illustrates an exemplary Ga-map in accordance with one embodiment. The In-map Al-map shows the alternating growth of InGaN and AlGaN layers. One should highlight that negligible indium signal is detected from the shells. Therefore, the intensity modulation in the shell originates from ultrathin GaN/AlGaN superlattice on the m-planes.

FIG. 2F is an illustration of an exemplary high magnification image in accordance with one embodiment. In one exemplary implementation, the high magnification image corresponds to a HAADF image of the dashed line boxed region 220 in FIG. 2B, showing the bottom InGaN QW has six periods of GaN/AlGaN shells while the top InGaN QW has one layer of AlGaN shell.

FIG. 2G is a graph of an exemplary EDS line scan along the arrow 291 as shown in the inset in accordance with one embodiment. The analyzed element is In. The In-map exhibits stronger signal for InGaN incorporated on the semipolar plane compared with that on c-plane, which is also confirmed by the EDS line scan along the horizontal arrow 291 in FIG. 2G. In one embodiment, FIG. 2G shows an exemplary EDS line scan along the arrow as shown in the inset TEM image, showing the increased Indium content on the periphery of the nanowire relative to the center of the nanowire along that line.

FIG. 2H is a graph of an exemplary EDS line scan along the arrow 295 as shown in the inset in accordance with one embodiment. The analyzed element is Al. The EDS line scan results along the vertical arrow 295 in FIG. 2h shows an exemplary negative Al composition gradient along the c-axis. The formation of such a unique structure can be attributed to the diffusion-controlled growth mechanism of III-nitride nanowire and the differences of incorporation energy on different crystalline planes.

In one embodiment, power-dependent PL properties of samples with AlGaN barrier (Sample A) and GaN barrier (Sample B) are investigated under resonant excitation with a 405 nm continuous wave (CW) laser at room temperature. The excitation power density is varied from ˜0.5 W/cm² to ˜400 W/cm².

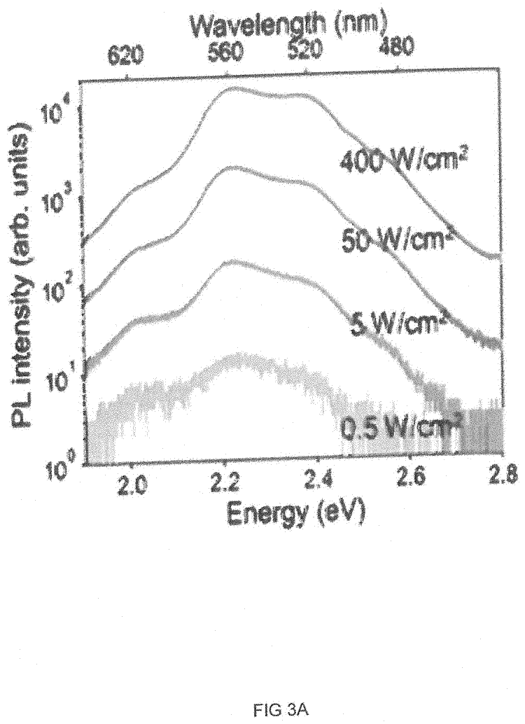

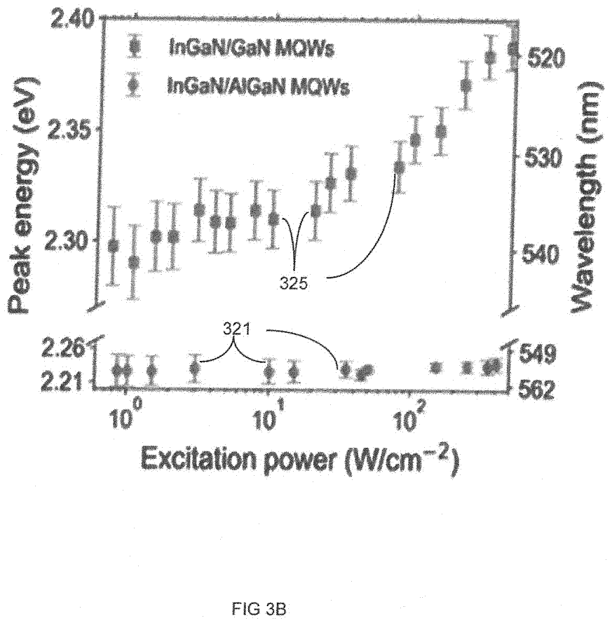

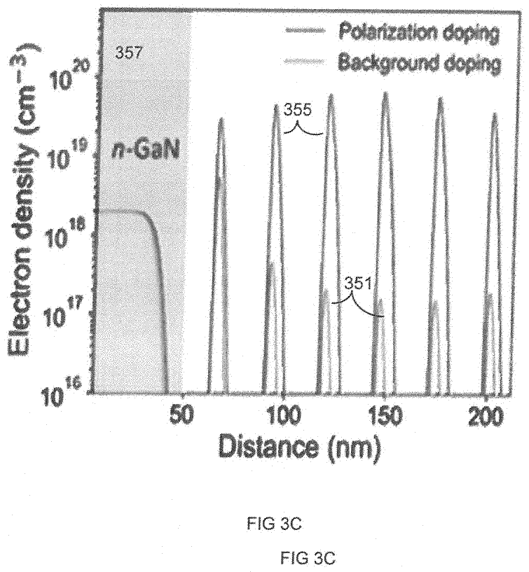

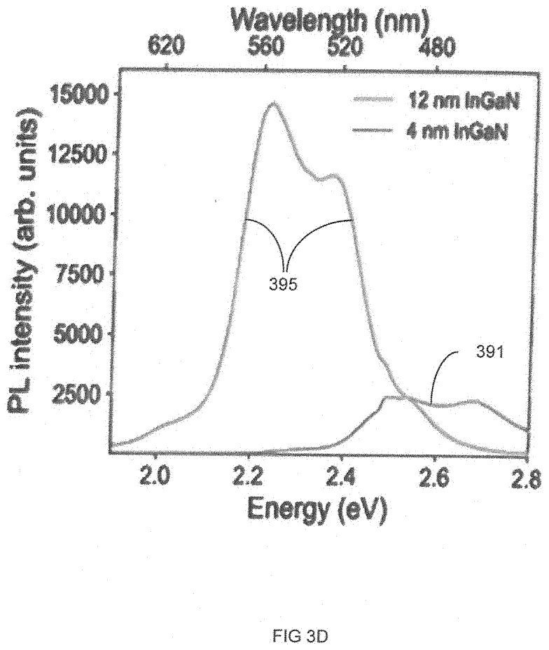

FIG. 3A is a graph of exemplary room-temperature power-dependent PL spectra of Sample A at 300 K with excitation power varied ˜3 orders of magnitude in accordance with one embodiment. Two dominant peaks can be identified from the spectra of Sample A as shown in FIG. 3A. The dominant peak at 2.23 eV (556 nm) can be attributed to the InGaN QWs on semipolar plane with a higher indium composition, whereas the peak around 2.36 eV (525.4 nm) can be attributed to the InGaN QWs on c-plane with a lower indium composition as shown in FIG. 2E. The internal electrostatic field within the InGaN QW of Sample A is calculated to be about 1.3 MV/cm with polarization and piezoelectric polarization considered. (Details can be found in Section 5 of Supporting info) Field of this strength along with QW thickness of ˜12 nm is expected to cause severe separation of carrier wavefunctions and blue-shifts in peak energy with increasing carrier density.

FIG. 31 is a graph of exemplary emission peak energy vs. excitation power for Sample A (e.g., circle dots 321, etc.) and Sample B (e.g., square dots 325, etc.) in accordance with one embodiment. It can be seen from the circle dots 321 of the example shown in FIG. 3B that over a wide excitation power density range, the sample exhibit an almost unchanged QW peak energy with increasing excitation power. In addition, the screening of QCSE comes along with a narrowing of the linewidth. Here, the lack of this behavior in the excitation power dependence of the full-width-half-maximum (FWHM) confirms one more time that the QCSE in the InGaN QWs of Sample A is negligible. The power-dependent PL spectra of Sample B can be found in Figure S5 and the peak energy with excitation power is shown in Figure B, wherein a shift of ˜100 meV (e.g., in the square dots 325, etc.) can be measured, because of the screening of QCSE within InGaN QWs.

The effect of Al incorporation on the carrier radiative recombination process can be related with the Al distribution in the active region. III-nitrides are polar materials and the grading of (Al,Ga)N composition along the c-axis induces polarization charges in the bulk nanowire, which further results in accumulated free charge carriers with opposite sign. In one embodiment, the Al content features a negative gradient along the [0001̅] which leads to a distribution of positive fixed charge in the shell region. With the presence of donor-type surface states and bulk shallow donors, the positive bound charges can subsequently induce mobile free electrons. The positive bound charges can subsequently induce mobile electrons in the shell, which could transfer to the InGaN QW in the nanowire core region and thus screen the internal electrostatic field. The electron density distribution is then calculated by considering an epilayer heterostructure includes six pairs of 12 nm In_{0.3}Ga_{0.7}N QWs/15 nm Al_{0.15}Ga_{0.85}N barriers on a 50 nm thick n-GaN, similar as the experimental design of InGaN/AlGaN heterostructure. An electron density of 3×10¹⁷ cm⁻³ is applied to the AlGaN barrier region, wherein the value is estimated based on the measured Al content change and induced polarization doping in FIG. 2h. The calculation is performed by solving the Schrödinger-Poisson equation iteratively.

FIG. 3C is a graph of exemplary calculated electron density distribution with the presence of polarization doping (e.g., curve 355, etc.)/background doping (e.g., curve 351, etc.) in accordance with one embodiment. The shaded region 357 indicates the n-GaN region. As shown in the polarization doping curve (e.g., curve 355, etc.) in exemplary FIG. 3C, the electron densities within the InGaN QWs range between 3×10¹⁹ cm⁻³ to 6×10¹⁹ cm⁻³ with the presence of induced free electrons, well above the reported Mott density of nitride QWs. In contrast, the electron density drops below the degenerate doping when a uniform background doping of ˜1×10¹⁶ cm⁻³ is adopted throughout the active region, further confirming the absent of QCSE effect is due to the relocation of induced free electrons. With the QCSE effect screened, it is expected that a simple increase in the active region volume by increasing the InGaN QW thickness can provide enhanced emission intensity and reduced Auger recombination within the QW.

FIG. 3D is a graph of an exemplary PL comparison of Sample A 395 and Sample C 391 measured under the same excitation power in accordance with one embodiment. FIG. 3D shows the PL of Sample C 391, which includes 4 nm thick InGaN QWs while other parameters are the same as Sample A, in accordance with one embodiment. It can be observed that the PL peak intensity of Sample A is ˜6 times that of Sample C. Meanwhile, there is a clear shift in emission peak energy cure 391 of Sample A compared with Sample C. Previous reports have suggested that AlGaN, due to a smaller lattice constant compared with GaN, can be used to compensate the tensile strain caused by InGaN in the active region, which enhances indium composition InGaN QW as a result of a smaller mismatch strain energy.

In one embodiment, the strain distribution in InGaN/(Al)GaN MQWs is examined using low angle angular dark field (LAADF) STEM. Sample D with single InGaN QW in GaN nanowire is grown for this implementation.

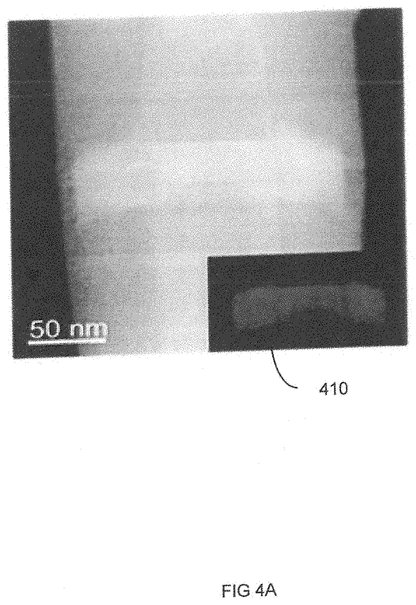

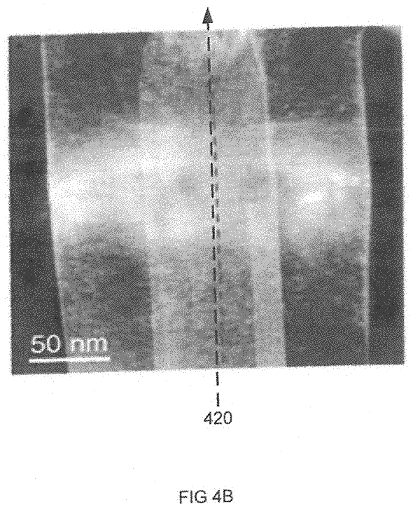

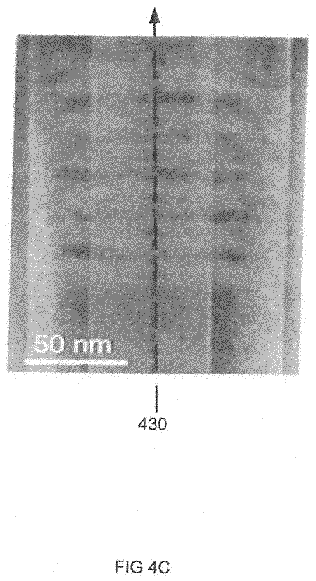

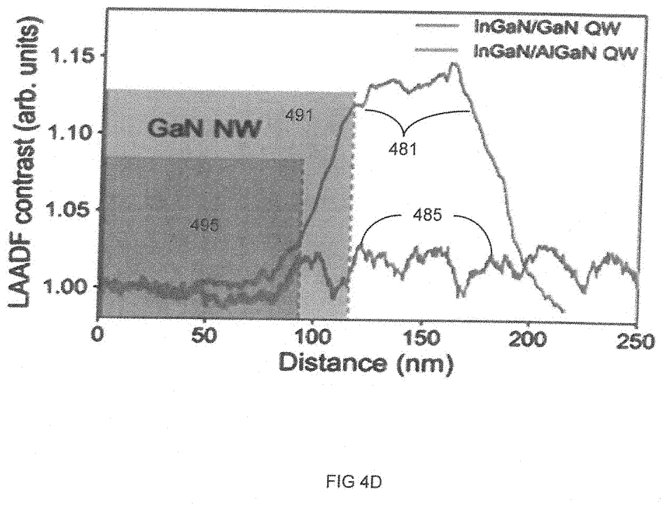

FIG. 4A is a block diagraph of an exemplary HAADF image of the active region of a sample in accordance with one embodiment. In one exemplary implementation, the inset 410 illustrates EDS mapping of In distribution in the active region of Sample D. FIG. 4A shows an exemplary HAADF image of the active region of Sample D. As is well known, the HAADF signals scale approximately with the atomic number, Z, and the high-Z cation sites dominate in the HAADF image, which is indium in this case and no strain effect can be detected. The inset 410 of FIG. 4A shows the EDS mapping of indium element, and the distribution agrees well with the high contrast region of the HAADF image. The LAADF signals are collected at 20-50 mrad and are very sensitive to the effects that can cause the dechanneling of the incident electron beam, such as phonons or strain fields. This method has been used in measuring strain distribution in Si/Ge heterostructures.

FIG. 4B is a block diagram of an exemplary LAADF image in accordance with one embodiment. In one exemplary implementation, the LAADF image corresponds to HAADF image of FIG. 4A. By matching the contrast variations in the simultaneously recorded LAADF image (e.g., FIG. 4B, etc.), the strained area can be located. It is seen that the strained area diffused into about 20 nm of the bottom and top GaN barrier. Above this range, the strain field decays below the dechanneling detection limit. The bright column in the center of the nanowire is attributed to the thickness variation caused by FIB sampling.

FIG. 4C is a block diagram of an exemplary LAADF image of the active region and underlying GaN of a sample in accordance with one embodiment. In one exemplary implementation, LAADF image the image corresponds to Sample A. FIG. 4C is an exemplary corresponding LAADF image of FIG. 2B, wherein the intensity change is significantly reduced across the active region compared with FIG. 4B.

FIG. 4D is a graph of an exemplary LAADF line profile along the dashed line 420 in FIG. 4b and dashed line 430 in FIG. 4C in accordance with one embodiment. The shaded region 491 indicates the GaN NW region in Sample D and shaded region 495 indicates the GaN NW region Sample C. Curve 481 corresponds to InGaN/GaN QW and curve 485 corresponds to InGaN/AlGaN QW. In one embodiment, FIG. 4D shows the LAADF line profile from the bottom GaN to the active region of Sample A and D while the signal is normalized to the respective bottom GaN to provide an estimate of the absolute strain field intensity in the active region. The observed peak value of InGaN/GaN is much higher than that obtained from InGaN/AlGaN QWs. The difference can be attributed to a reduced average lattice constant in the active region when AlGaN barrier is adopted and hence a forced pseudomorphic growth of the entire MQW stack with significantly reduced strain relaxation. With reduced misfit strain energy, the indium composition increases, which is consistent with the longer emission wavelength observed from Samples with AlGaN barrier.

In one embodiment, μLED fabrication is performed by standard passivation, lithography, reactive ion etching and metallization processes. Additional description of exemplary various fabrication process aspects is set forth in the Methods section below. Devices with sizes of ˜900 nm×900 nm are fabricated.

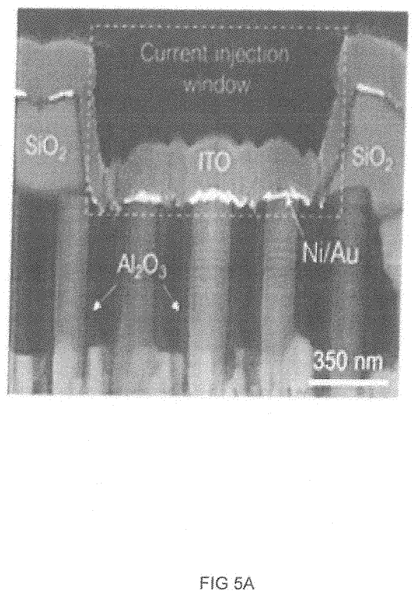

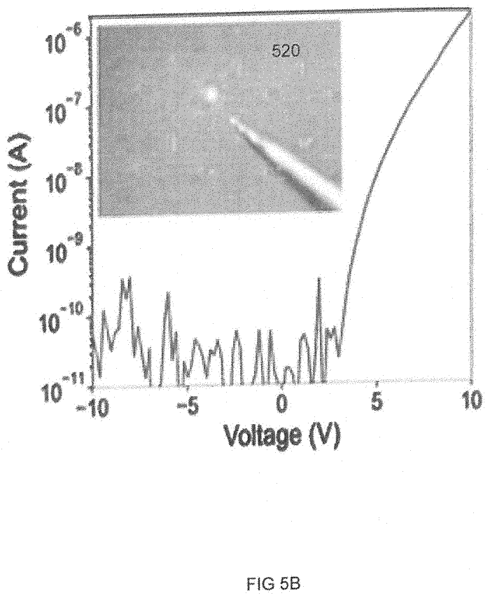

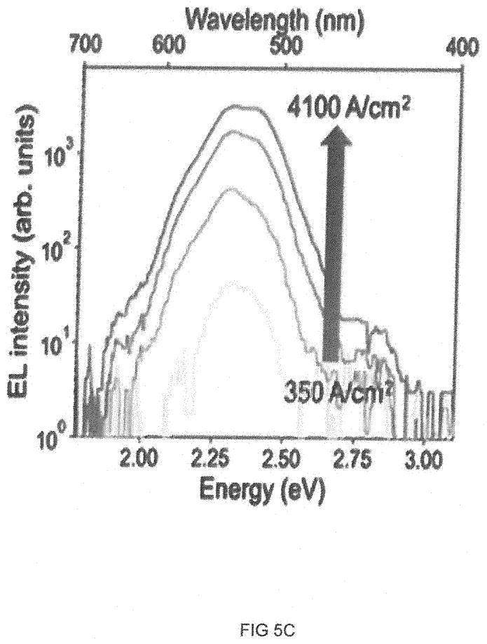

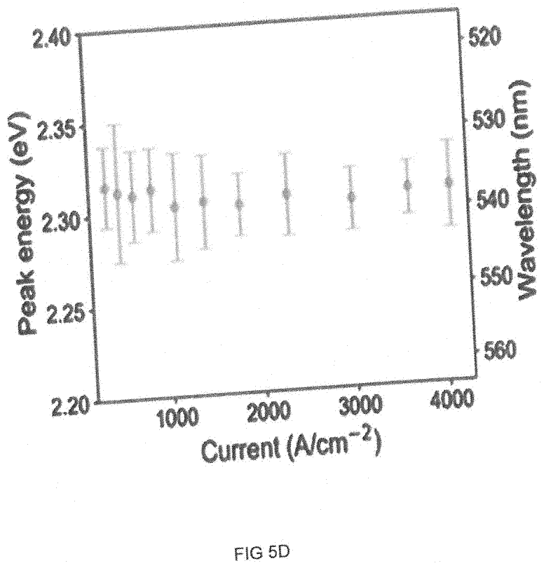

FIG. 5A is a block diagram of an exemplary HAADF-STEM image of the cross section of the as fabricated InGaN/AlGaN μLED with areal size of ˜900×900 nm² in accordance with one embodiment. The current injection window is delineated by the dashed box. In one exemplary implementation, FIG. 5A shows a cross-sectional HAADF-STEM image of a representative device with different regions highlighting different materials, including Al₂O₃ passivation layer regions, SiO₂ insulation layer regions, Ni/Au layer regions, and ITO regions. The Al₂O₃ passivation layer regions correspond to the sidewalls of nanowires to prevent leakage current caused by metal deposition. The top p-GaN of the nanowires is insulated by ˜320 nm SiO₂ (dark cyan false-colored region) except the nanowires located within the current injection window as indicated by the dashed rectangle in FIG. 5A. Metallization of ˜2.5 nm Ni/2.5 nm Au/180 nm ITO is used to form Ohmic contact with the top p-GaN of the nanowires after annealing at 550° C. in nitrogen ambient for 1 min. Each μLED includes several individual nanowires with InGaN/AlGaN MQWs as the active region.

FIG. 5B in a graph of an exemplary I-V characteristics of as-fabricated InGaN/AlGaN nanowire μLEDs measured at room temperature in accordance with one embodiment, wherein negligible leakage current is observed at reverse bias. In one exemplary implementation, the inset 520 illustrates an optical image of the bright green emission measured from a μLED under injection current of ˜100 A/cm². The current-voltage (I-V) characteristics of the as fabricated μLEDs show negligible leakage current under reverse bias as shown in exemplary FIG. 5B, and the rectification ratio at ±8V is over 4 orders of magnitude. The μLEDs are measured with a turn-on voltage of ˜2 V, and EL can be detected at current density as low as ˜0.3 A/cm². The inset of FIG. 5B shows an optical image of the bright green emission measured from a μLED under injection current of ˜100 A/cm².

FIG. 5C is a graph of an exemplary EL spectra measured under injection currents from 350 A/cm² to 4,100 A/cm² for an InGaN/AlGaN μLED in accordance with one embodiment. The current-dependent EL spectra are shown in exemplary FIG. 5C, wherein the dominant peak emission is at ˜2.3 eV (537 nm).

FIG. 5D is a graph of exemplary variation of peak position vs. injection current in accordance with one embodiment. FIG. 5D shows the integrated EL intensity and the peak energy with injection current, in accordance with one embodiment. With increasing injection current the peak energy shifts from˜2.313 eV (536 nm) to 2.309 eV (537 nm). This slight red shift cannot be explained by the QCSE related transitions reported in conventional InGaN/GaN MQWs. Instead, it can be explained by a combination of current-induced heating effect and bandgap renormalization. Significantly, in the wide InGaN QWs used in one embodiment, the impact of Auger recombination can also be significantly suppressed due to reduced carrier density within the InGaN QWs, which can further promise reduced efficiency droop at elevated current density levels.

In conclusion, the QCSE effect can be significantly suppressed through adopting AlGaN barriers in InGaN/AlGaN MQWs. In one embodiment, this is achieved through a formation of AlGaN/GaN shell around the active region and with Al composition gradient from bottom to the top of the active region. The free electrons induced by the polarization positive bond charges can effectively screen the internal electric field within the InGaN QWs. Moreover, AlGaN as a quantum barrier can effectively compensate the tensile strain caused by InGaN QW in GaN nanowire. The strain distribution within the active region is directly imaged and analyzed by LAADF-STEM. The strain compensation effect results in an enhanced indium incorporation and thus a longer emission wavelength, and this is achieved without sacrificing the oscillation strength within the QW. In addition, green-emitting nanowire μLEDs on Si substrate with a sub-micrometer size have been demonstrated for the first time. The active region of the μLEDs includes InGaN/AlGaN MQWs and detailed current dependent EL measurements show that negligible QCSE is observed. This work provides a new approach for designing the active region of high-performance multi-color μLEDs. Moreover, the monolithic integration of μLED on Si substrate is of great importance for next generation display, optical communication, and other optoelectronic devices.

In one embodiment, the nanowire μLED heterostructures are grown on a relatively thin N-polar GaN/AlN buffer layer on Si wafer. The SEM image of an exemplary as-grown substrate is shown in Figure Sla, wherein the pit density is ˜8×10⁸ cm⁻². Before performing SAE on the N-polar GaN on Si substrate, a Ti patterning process is adopted. Before performing SAE on the N-polar GaN on Si substrate, a Ti patterning process is adopted. Additional explanation can be found in:
Liu, X., Wu, Y., Malhotra, Y., Sun, Y. & Mi, Z. Micrometer scale InGaN green light emitting diodes with ultra-stable operation. Applied Physics Letters 117, 011104 (2020);
Liu, X. et al. N-polar InGaN Nanowires: Breaking the Efficiency Bottleneck of Nano and Micro LEDs. Photonics Research (2021); and
Liu, X. et al. High efficiency InGaN nanowire tunnel junction green micro-LEDs. Applied Physics Letters 119, 141110 (2021),
   which are all incorporated herein by reference.

### Methods:

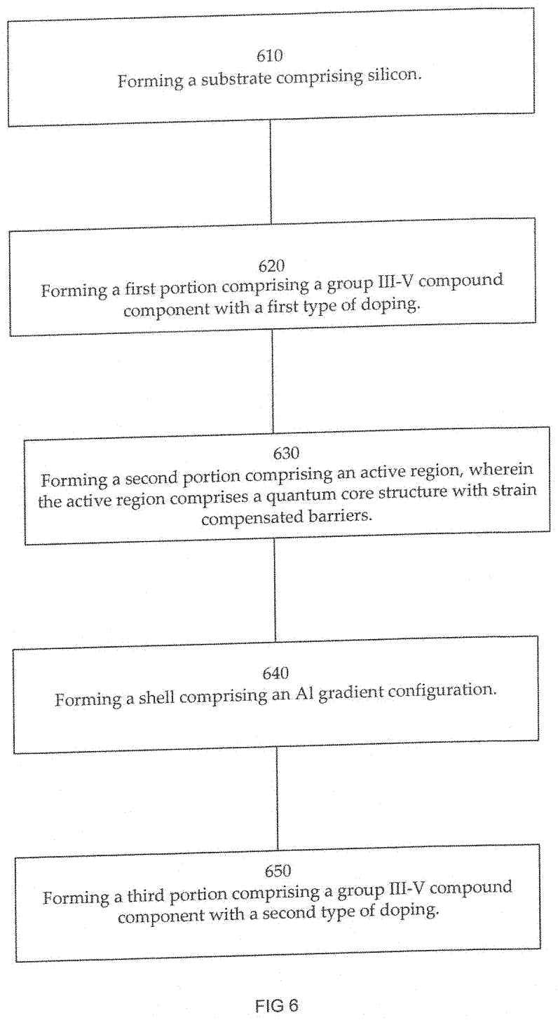

FIG. 6 is a flow chart of method 600 in accordance with one embodiment.

In block 610, a substrate comprising silicon is formed.

In block 620, a first portion is formed comprising a group III-V compound component with a first type of doping.

In block 630, a second portion is formed comprising an active region. In one embodiment, the active region comprises a quantum core structure with strain compensated barriers. The second portion is coupled to the first portion.

In block 640, a shell is formed. The shell is coupled to the second portion. The shell comprises an Al gradient configuration. In one embodiment, the gradient forms a negative Al gradient.

In block 650, a third portion is formed comprising a group III-V compound component with a second type of doping. The third portion is coupled to the second portion.

Epitaxy: In one embodiment, the growth of N-polar GaN epilayer on 2 inch Si(111) wafers is performed in a Veeco GENxplor system. The growth started with an unintentionally doped (UID) AlN buffer layer of ˜100 nm and followed by a Si-doped GaN layer of ˜500 nm at a substrate temperature of 770° C., nitrogen flow of 0.3 sccm and plasma power of 350 W. After patterning and standard solvent cleaning, wafer is loaded into a Veeco GEN II system for subsequent nanowire device structure growth. The Ti masked wafer is first nitridized at 400° C. for 10 mins under a nitrogen plasma flow rate of 1 sccm. The n-GaN segment is grown at 690° C., Ga beam equivalent pressure of 3.5×10⁻⁷ Torr and nitrogen flow of 0.5 sccm. The estimated growth rate is ˜3 nm/s. The active region is grown at a substrate temperature of 560° C., Ga beam equivalent pressure (BEP) of 6×10⁻⁸, In BEP of 1×10⁻⁷ Torr and Al BEP of 8×10⁻⁹ Torr. The nitrogen flow rate is increased to 0.7 sccm to enhance indium incorporation during active region growth. The p-GaN is grown at 690° C. for 30 mins. Mg BEP of 8×10⁻⁹ Torr is used.

Fabrication: In one embodiment, the fabrication starts with atomic layer deposition (ALD) of Al₂O₃ to fill the air gap and planarize the nanowire array. The top p-GaN of each individual nanowire is revealed by a fluoride-based reactive ion etching (RIE) process. Plasma-enhanced chemical vapor deposition of 320 nm SiO₂ is performed as an insulation layer followed by lithography and RIE etching to open the current injection window for each sub-micrometer LED devices. Metal stacks including 2.5 nm Ni/2.5 nm Au/180 nm ITO are used as p-metal contact. ITO deposition is performed using sputtering process to ensure an excellent coverage on the sidewall of the SiO₂ insulation layer. Chlorine-based RIE process is used to etch down into the n-GaN. 20 nm Ti/8 nm Au is deposited for n-metal contact. The device is annealed in N₂ ambient at 550° C. for 1 min.

Characterizations: In one embodiment, structural properties of the samples are analyzed using a JEOL JEM-3100R05 analytical electron microscope with double Cs-correctors operated at 300 keV. EDS mapping are performed using Thermo Fisher Talos F200X analytical electron microscope. The I-V characteristics are measured using a Keithley 2400 voltage source meter. The PL and EL emission are collected by an optical fiber and spectrally resolved by high-resolution spectrometers, and then detected by liquid nitrogen/thermal electrically cooled CCD cameras.

Thus, efficient and effective light emitting devices are presented. In one embodiment, high-performance tunnel junction deep ultraviolet (UV) light-emitting diodes (LEDs) are created using plasma-assisted molecular beam epitaxy. The device heterostructure is grown under slightly Ga-rich conditions to promote the formation of nanoscale clusters in the active region. The nanoscale clusters can act as charge containment configurations. In one embodiment, an active region comprises Ga(Al)N quantum well heterostructures with barrier layer thicknesses varying (e.g., decreasing, etc.) from a n-AlGaN side to a p-AlGaN side to enhance hole injection and transport. In one exemplary implementation the barrier layer thicknesses nanometers.

Although the subject matter has been described in language specific to structural features and/or methodological acts, it is to be understood that the subject matter defined in this disclosure is not necessarily limited to the specific features or acts described above. Rather, the specific features and acts described above are disclosed as example forms of implementing this disclosure.

Some portions of the detailed descriptions are presented in terms of procedures, logic blocks, processing, and other symbolic representations of operations on data bits within a computer memory. These descriptions and representations are the means generally used by those skilled in data processing arts to effectively convey the substance of their work to others skilled in the art. A procedure, logic block, process, etc., is here, and generally, conceived to be a self-consistent sequence of steps or instructions leading to a desired result. The steps include physical manipulations of physical quantities. Usually, though not necessarily, these quantities take the form of electrical, magnetic, optical, or quantum signals capable of being stored, transferred, combined, compared, and otherwise manipulated in a computer system. It has proven convenient at times, principally for reasons of common usage, to refer to these signals as bits, values, elements, symbols, characters, terms, numbers, or the like.

It should be borne in mind, however, that of these and similar terms are associated with the appropriate physical quantities and are merely convenient labels applied to these quantities. Unless specifically stated otherwise as apparent from the following discussions, it is appreciated that throughout the present application, discussions utilizing terms such as “processing”, “computing”, “calculating”, “determining”, “displaying” or the like, refer to the action and processes of a computer system, or similar processing device (e.g., an electrical, optical, or quantum, computing device), that manipulates and transforms data represented as physical (e.g., electronic) quantities. The terms refer to actions and processes of the processing devices that manipulate or transform physical quantities within a computer system's component (e.g., registers, memories, other such information storage, transmission or display devices, etc.) into other data similarly represented as physical quantities within other components.

The foregoing descriptions of specific embodiments of the present invention have been presented for purposes of illustration and description. They are not intended to be exhaustive or to limit the invention to the precise forms disclosed, and obviously many modifications and variations are possible in light of the above teaching. The embodiments were chosen and described in order to best explain the principles of the invention and its practical application, to thereby enable others skilled in the art to best utilize the invention and various embodiments with various modifications as are suited to the particular use contemplated. It is intended that the scope of the invention be defined by the Claims appended hereto and their equivalents. The listing of steps within method claims do not imply any particular order to performing the steps, unless explicitly stated in the claim.

What is claimed is:

1. A light emitting device comprising:
a substrate comprising silicon;
a first portion comprising a group III-V compound component with a first type of doping;
a second portion comprising an active region, wherein the active region comprises a quantum core structure with strain compensation barriers and polarization doping, wherein the second portion is coupled to the first portion;
a shell coupled to the second portion, wherein the shell comprises a gradient configuration with piezoelectric field compensation characteristics; and
a third portion comprising a group Ill-V compound component with a second type of doping, wherein the third portion is coupled to the second portion.

2. The light emitting device of claim 1, wherein the strain compensated barriers form multiple quantum wells.

3. The light emitting device of claim 1, wherein the strain compensation barriers include AlGaN.

4. The light emitting device of claim 1, wherein the strain compensated barriers include AlGaN in a configuration that compensates tensile strain within the active region.

5. The light emitting device of claim 1, wherein the strain compensated barriers include AlGaN in a configuration that induces polarization charges.

6. The light emitting device of claim 1, wherein the strain compensated barriers include AlGaN configured to enhance indium incorporation.

7. The light emitting device of claim 1, wherein the shell comprises AlGaN with a negative Al composition gradient.

8. The light emitting device of claim 1, wherein the first portion, second portion, and third portion comprise nanostructured components.

9. The light emitting device of claim 1, wherein the first portion, second portion, and third portion comprise a nanowire.

10. The light emitting device of claim 1, wherein the first portion, second portion, third portion, and shell form a nanowire with polarization doping configured to enable stable operation and light emission.

11. The light emitting device of claim 7, wherein the light emission is in a long wavelength range.

12. The light emitting device of claim 1, wherein the light emitting device is configured to operate with negligible quantum-confined Stark effect.

13. The light emitting device of claim 1, wherein the light emitting device is configured to create stable wavelength emissions.

14. The light emitting device of claim 1, wherein the light emitting device is a micro-light emitting diode (μLED) with lateral dimensions less than 10 um.

15. The light emitting device of claim 1, wherein the substrate includes electronics.

16. The light emitting device of claim 1, wherein the substrate includes CMOS electronics.

17. The light emitting device of claim 15, wherein the light emitting device is a micro-light emitting device and the substrate includes electronics monolithically integrated in the micro-light emitting device

18. A method comprising:
forming a substrate comprising silicon;
forming a first portion comprising a group III-V compound component with a first type of doping;
forming a second portion comprising an active region, wherein the active region comprises a quantum core structure with strain compensated barriers, wherein the second portion is coupled to the first portion;
forming a shell coupled to the second portion, wherein the shell comprises an Al gradient configuration; and.
forming a third portion comprising a group III-V compound component with a second type of doping, wherein the third portion is coupled to the second portion.

19. The method of claim 18, wherein forming the substrate includes forming electronic components in the silicon.

20. The method of claim 18, wherein the substrate, the first portion, the second portion, shell and third portion are monolithically formed.

21. The method of claim 18, wherein the first portion, the second portion, shell, and third portion are grown on substrate in a configuration that reduces thermal accumulation within the device area.

22. The method of claim 18, wherein the substrate, the first portion, the second portion, shell and third portion comprise polarization doping.
